(19) United States
(12) Patent Application Publication
(10) Pub. No.: US 2012/0066023 A1
(43) Pub. Date: Mar. 15, 2012

(54) Green Energy Database Including Verifiable Information for Implementing a National Level Green Energy Policy

(76) Inventors: Mingyao XIA, Shenzhen (CN); Eric GRUBEL, Thousand Oaks, CA (US); Dan CASTELLANO, Cupertino, CA (US)

(21) Appl. No.: 13/270,896

(22) Filed: Oct. 11, 2011

Related U.S. Application Data
(63) Continuation-in-part of application No. 13/197,623, filed on Aug. 3, 2011.
Application No. 13/197,623 is a continuation-in-part of application No. 13/153,194, filed on Jun. 3, 2011.
Application No. 13/153,194 is a continuation-in-part of application No. 13/032,454, filed on Feb. 22, 2011.

(51) Int. Cl. G06Q 10/00; G01R 21/133; G06F 19/00; G06F 1/28

(52) U.S. Cl. 705/7.29; 700/295; 702/62

(57) ABSTRACT

A green energy, smart-grid residential system collects power usage information from a plurality of connected homes by progressively integrating information collected from each of the individual homes using a group of sensor devices. Such information is compiled to usable format using distributed computers. The in-home sensor devices include an intelligent master device, and one or more of a communication and power switch device, a ZigBee® enabled switch device, and a power control switch device, each of which typically operate over a power line communication network. The master device collects, compiles, and communicates the collected data to the Web or outside world. The information from a number of these homes in a local area is consolidated using local distributed processors on the Web and provided to a main processing unit for compilation and integration with other regional inputs for use in national policy decision making.

### CROSS REFERENCE TO RELATED APPLICATIONS

This application a continuation-in-part of U.S. patent application Ser. No. 13/197,623, filed Aug. 3, 2011, which, in turn, claims priority to U.S. patent application Ser. No. 13/153,194, filed Jun. 3, 2011, which application claims priority to U.S. patent application Ser. No. 13/032,454, filed Feb. 22, 2011, each of which is incorporated herein in its entirety by this reference thereto.

### BACKGROUND OF THE INVENTION

1. Technical Field

This invention relates to the collection and compilation of data to help understand power usage trends. More particularly, the invention relates to the collection and compilation of such data to help make policy decisions in connection with reducing the carbon footprint of in-home power consuming equipment.

2. Description of the Background Art

Communication using power line has been limited, until recently, to a few local area networks (LANs) within homes or offices or, at best, within apartment complexes. Power line communication has also been used in a limited number of applications where other types of communication methods do not provide sufficient security and remote connectivity, such as for power line control applications.

Basic devices for connecting to the power line for communication and power supply have been designed and are used to provide service within LANs. But, due to the availability of more efficient competing technologies, the infrastructure for power line communication (PLC) has never been developed enough to make it a mainstream technology. This can be attributed to various reasons, including the higher cost of available devices, the lack of suitable devices for communication using the PLC technology, etc. The result has been that PLC has not found a path for growth in the standard voice and data communication field catered to by technologies such as xDSL, cell phones, and satellite communications.

Today there is an emerging need for the ability to collect information and provide remote control capability for appliances in the home to reduce the carbon footprint of the home. There is also a need to use such collected information, for example information concerning energy use, to enhance our understanding of power and other utility use trends, and thus develop a public policy that leads to optimum use of resources in a way that reduces the carbon footprint of the home. This would require the ability to capture and compile the data collected and to convert it to a usable form, if such data is to be used to enhance our understanding and provide meaningful inputs to national level utility policy planning.

### SUMMARY OF THE INVENTION

An embodiment of the invention provides in-home or office data collection, with the capability to consolidate the collected information locally from groups of homes, and to supply this information to a national policy making body. This approach caters to the collection and compilation of the needed information through an available power line communication (PLC) network of the type that enables communication and streaming media capability in the home.

Thus, in an embodiment a green energy smart-grid residential system collects power usage information from a plurality of connected homes by progressively integrating information collected from each of the individual homes using a group of sensor devices; and a method that compiles such information to a usable format via distributed computers. The in-home sensor devices for collecting power usage information can include an intelligent master device, and one or more of a communication and power switch device, a ZigBee® enabled switch device, and a power control switch device, each of which typically operate over a PLC network. The master device collects, compiles, and communicates the collected data to the Web or outside world. The information from a number of these homes in a local area is consolidated using local distributed processors on the Web and provided to a main processing unit for compilation and integration with other regional inputs for use in national policy decision making.

### BRIEF DESCRIPTION OF THE DRAWINGS

FIG. 1 is a block schematic diagram showing a power switch (SW) device;

FIG. 2 is a block schematic diagram showing a data communication (Ethernet) enabled switch (ETH) device;

FIG. 3 is a block schematic diagram showing a ZigBee® enabled switch (Z-SW) device;

FIG. 4 is a block schematic diagram showing a master (MST) device;

FIG. 5 is a block schematic diagram showing a an in-home connection for sensor devices that monitor power and utility usage and communication;

FIG. 6 is a block schematic diagram showing the compilation of power and utility use per home group, using computer systems over a wide area network (WAN), and the compilation from multiple home groups for use in national level green energy planning;

FIG. 7 is a table showing a sample compilation of power use per connected appliance, as well as utility use in the home;

FIG. 8 is a table showing a sample compilation of power and other utility use from a group of connected homes;

FIG. 9 is a flowchart showing the setup of a green energy smart-grid residential system for use in creating a national green energy data base; and

FIG. 10 is a flowchart showing the operation of the smart-grid residential system for generating a green energy database.

### DETAILED DESCRIPTION OF THE INVENTION

An embodiment of the invention provides a green energy, smart-grid residential system that collects power use information from a plurality of connected homes by progressively integrating information that is collected from each of the individual homes via the use of a group of sensors. Such information is compiled to a usable format using distributed computers. The in-home sensors that are used to collect power usage information include an intelligent master device and one or more of a communication and power switch, a ZigBee® enabled switch, and a power control switch, each of which typically operate over a power line communication (PLC) network. The master device collects, compiles, and communicates the collected data to the Web. The information from a number of homes in a local area is consolidated using local distributed processors on the Web and provided to a main processing unit for compilation and integration with other regional inputs for use in national policy decision making.

The development of green technologies and the need for monitoring and control of the carbon footprint of homes and offices has created a need to assess power and other utility use patterns remotely. This requires the ability to measure power use and determine the impact that any policy decisions may have in affecting such use. It is also necessary to have the ability to supervise and control the use of power remotely and to provide the consumer with the ability to monitor and control power use on a micro level. The consumer is able to exercise the necessary constraints on use if the proper information, incentives, and tools are provided. The usage pattern and collected utility data on a macro level is needed for use in developing policies that are beneficial to the overall reduction in the carbon footprint at the home and office level, as well as on a national level. Empowering the individual and the society to exercise the necessary constraints and controls by monitoring the power and other utility use is an area where an in-home or office power line communication (PLC) network can be effectively and optimally used.

The PLC network is a network that is capable of collecting and compiling the power use of connected appliances and also collecting other utility use information. The detailed operation of the sensor units and the in-home PLC network are described in U.S. patent application Ser. No. 13/197,623, filed Aug. 3, 2011 which, in turn, claims priority to U.S. patent application Ser. No. 13/153,194, filed Jun. 3, 2011 which, in turn, claims priority to U.S. patent application Ser. No. 13/032,454, filed Feb. 22, 2011, each of which claim inventions made by the same inventors and assigned to the same assignee, and each of which is incorporated herein in its entirety by this reference thereto.

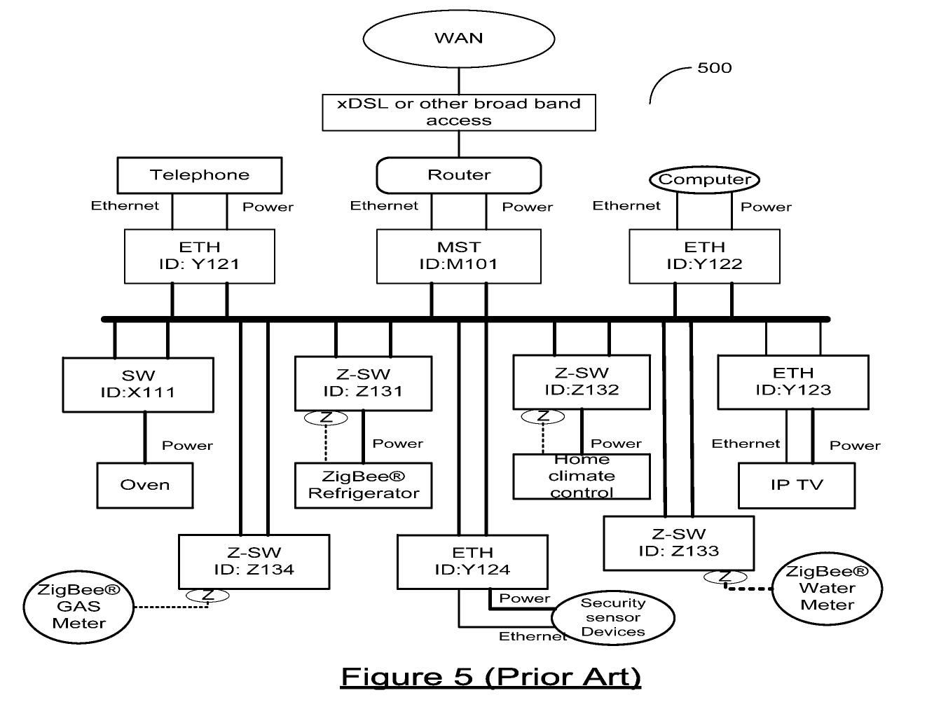

FIG. 5 shows a PLC network with four different sensor devices. The PLC network typically performs data collection with a master device (MST) connected to a router that connects to the wide area network, and at least one of a power switch (SW), a data communication (Ethernet) enabled power switch (ETH), and a ZigBee® enabled switch (Z-SW). These devices, when connected to the PLC network and when also connected to appliances that are plugged into the respective power plugs of the devices and/or water meters, gas meters, and other utility meters, and/or connected by ZigBee® modules of Z-SW respectively, enable the collection of power use information and other utility information. The sensors also provide for remote control of power use of connected appliances. This capability is established using the ETH, in addition to the communication and streaming media capability established using the PLC network. These devices also provide the capability to remotely control connected appliances, as described and included in the above referenced patent applications. The use of a specific device is dictated, at least in part, by cost considerations for the overall PLC network. The selective use of these devices allows only the appropriate capabilities for the specified application within the home or office, thus reducing the overall cost of use in the home or office.

### The Power Control Switch Device (SW)

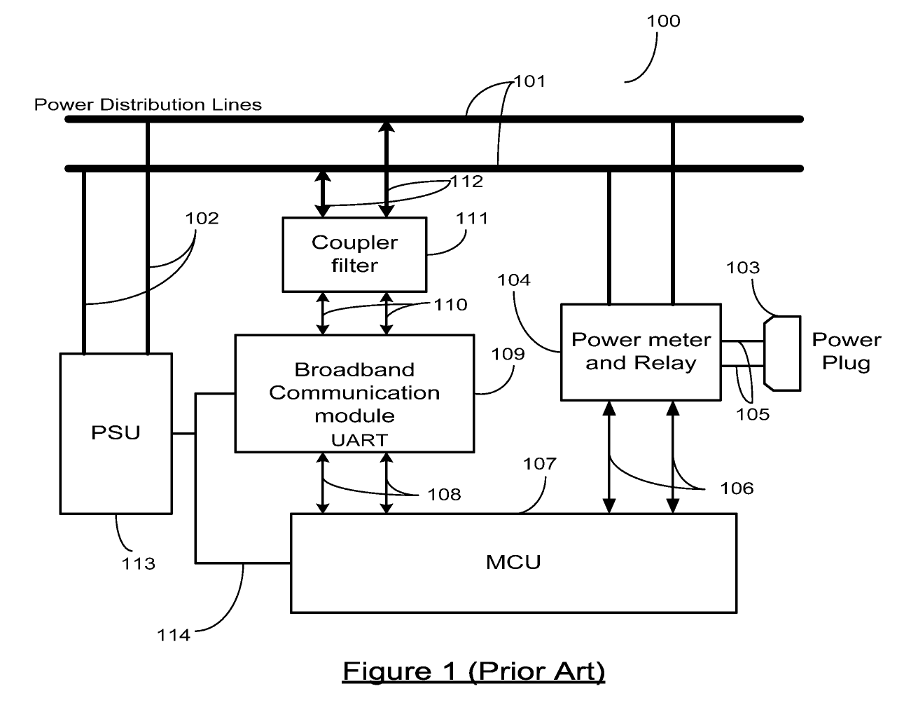

FIG. 1 is a block schematic diagram showing the SW 100. The SW 100 allows an appliance in the home or office to be connected to the power supply through a power plug on the device. The device provides for the monitoring of power consumption with capability for remote control of the power supply to the connected appliance via the Internet and the PLC network.

The SW 100 has a power plug that is connected to the AC power distribution lines 101 through a power meter and relay 104.

The relay in the power meter and relay module 104 provides the capability to switch on or switch off the supply to the power plug 103 remotely. It also allows for controlling the power supplied to the plug, where a power control module is included in the power meter and relay module 104.

The power meter in the power meter and relay module 104 monitors the power usage by the appliances connected to the power plug. The power meter and relay module 104 is connected via bi-directional communication links 106 to a microcontroller (MCU) 107 similar to an Intel® 8051. The microcontroller accepts the information on the power usage and compiles it prior to transfer to the broadband communication module 109. The power meter in the power meter and relay module 104 continuously monitors the flow of power to the power plug 103 and feeds the information to the MCU 107 through the communication links 106. The power usage information is compiled by the MCU 107 and sent to a broadband communication module 109 via communication links 108 which are connected to a UART enabled port on the communication module 109 for onward transmission over the PLC network.

### The Data Communication (Ethernet) Enabled Switch Device (ETH)

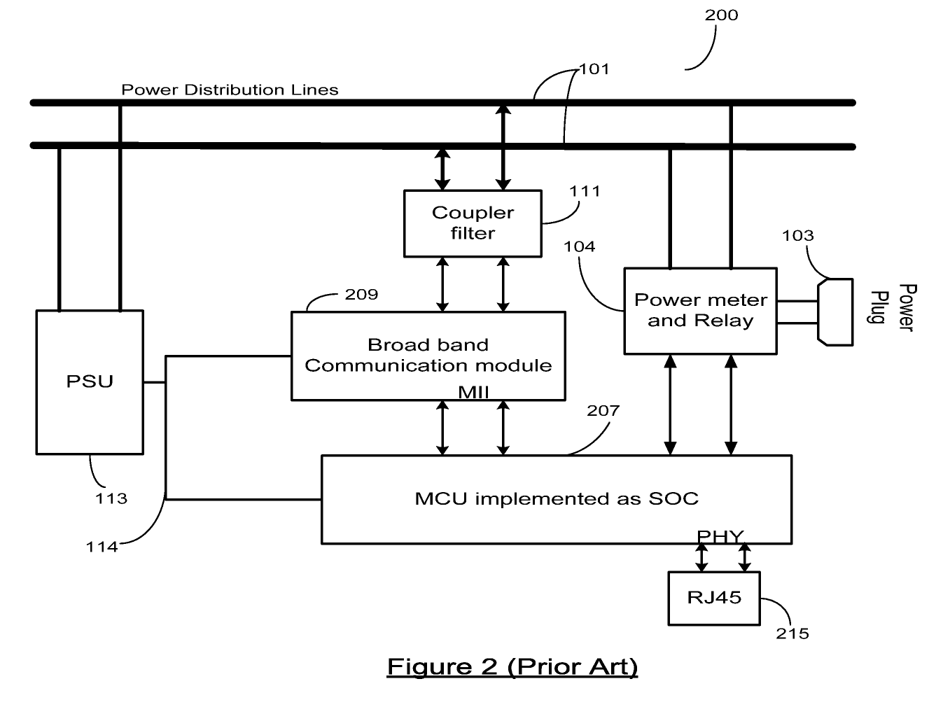

FIG. 2 is a block schematic diagram showing the ETH 200. The ETH 200 allows an appliance in the home or office to be connected to the power supply through the ETH 200 and provides for the monitoring of power consumption with capability for remote control of the connected appliance. The ETH 200 also provides the capability for broadband PLC-based data communication, where the data and communication devices are connected to the power distribution line through a communication port, typically an Ethernet port on the ETH 200. Multiple ETH 200 units can be used to establish a PLC based local area network (LAN) for communication.

The ETH 200 is a combination of two sub-units: a broadband PLC sub-unit, and a SW sub-unit similar to SW 100.

The SW sub-unit in this instantiation (ETH 200) uses broadband communication for information transfer on power usage and remote control of connected appliances over an Internet connection.

The broadband PLC Ethernet bridge adaptor module includes a 200 Mbps communication sub-unit for broadband sharing including, for example, on line gaming, voice over Internet protocol (VoIP), Internet protocol television (IPTV), and for audio and video streaming.

In FIG. 2, the communication subunit comprises an RJ45 connector 215 for establishing a connection to the subunit through a built-in PHY on an MCU 207. The power monitoring and control information of the associated power plug 103 is collected by the power meter and relay unit 104 and sent to the MCU 207. The information is cached and processed by the MCU 207 and then passed to the broadband communication module 209 through a media independent Interface (MII) port on the communication module 209.

The communication module 209, in this case, is common for communication and for power usage and status information transfer and control. Here, the communication module 209 is used to convert the incoming data stream into the broadband format used for PLC. The switch sub-unit of the ETH 200 operates similar to the SW 100. The power usage and power plug status information collected by the power meter and relay module 104 are also passed through the MCU 207 to the broadband communication module 209 for conversion to an output information stream using the broadband PLC format. Both the data stream and the power usage and status information stream are then transferred from the communication module 209 to the power distribution lines 101 in the home or office through the coupler filter module 111. Similarly, the communication module 209 receives the incoming communication data streams and the command and control instructions that are sent to the ETH 200 and passes them to the respective modules of the ETH 200 for processing.

The broadband communication module 209 is also enabled with a unique address so that communication to it and from it can be identified. Because the broadband communication elements are bidirectional, the broadband communication module can send and receive full duplex broadband communication between itself and any communication device connected to the RJ45 connector 215 via the MCU 207. Similarly, the communication module 209 can send out information streams comprising the power usage and status of the plug to the AC power distribution lines 101, and receive command and control information streams from the AC power distribution lines 101.

The received data and command and control information streams are decoded, the address is checked to see if it correct, and the streams are decrypted, if needed, based on the address. The communication module 209 then converts the received data stream into an analog format and sends it through the Mil interface of the MCU for transfer through the PHY to the RJ45 module 215, and thence to the connected customer device. Similarly, the communication module sends the command and control information to the MCU 207 for interpretation. The MCU 207 then generates instructions to the power meter and relay module 104 that are used by the power meter and relay module 104 to control the power flow to the power plug 103, and thence to the appliance connected to the power plug 103.

The use of multiple ETH 200 devices within a home or office enables PLC local area network connectivity within the home or office. Here, the disclosed use of broadband communication within the PLC LAN, using the ETH devices, enables streaming media delivery capability and IPTV delivery capability for connected display devices, connected to appropriate communication units within the PLC LAN.

### The ZigBee® Enabled Switch Device (Z-SW)

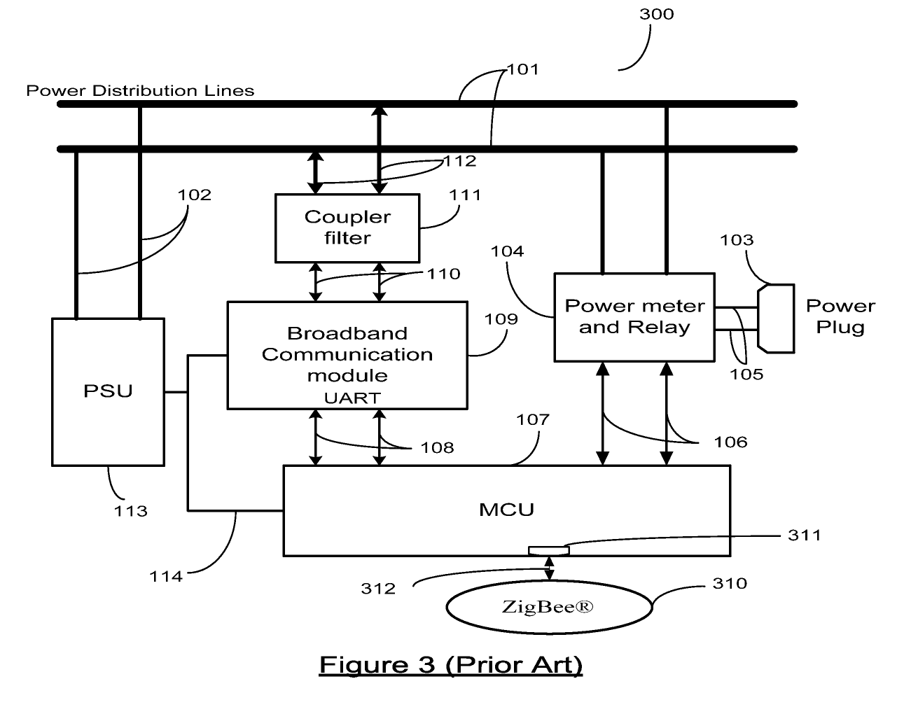

FIG. 3 is a block schematic diagram showing the Z-SW 300 device having an integrated ZigBee® unit 310. This allows an appliance in the home or office to be connected to the power supply and power line communication link through the Z-SW 300 which incorporates the ZigBee® device 310. The Z-SW 300 provides for the monitoring of power consumption with capability for remote control of the power flow to the connected appliance via the Internet. The ZigBee® unit 310 provides for additional operational control and monitoring through the wireless connection to ZigBee® technology enabled appliances.

The Z-SW 300 has a power plug 103 that is connected to the AC power distribution lines 101 through a power meter and relay 104. The relay in the power meter and relay module 104 provides the capability to switch on or switch off the supply to the power plug 103 remotely. It also allows for controlling the power supplied to the plug when a power control module is included in the power meter and relay module 104.

The power meter in the power meter and relay module 104 monitors the power usage by the appliances connected to the power plug. The power meter and relay module 104 is connected via bi-directional communication links 106 to a microcontroller (MCU) 107. The MCU 107 accepts the information on the power usage from the power meter and relay module 104 and compiles this information prior to transfer to the broadband communication module 109. The power meter in the power meter and relay module 104 continuously monitors the flow of power to the power plug 103 and feeds the information to the MCU 107 through the communication links 106. The power usage information is compiled by the MCU 107 and sent to a broadband communication module 109 via communication links 108 connected to a UART enabled port on the communication module 109, thus enabling the compiled data to be transmitted out.

The operational commands for the ZigBee® unit 310 of the Z-SW 300 are received over the power line at the broadband communication module 109 as a data stream. These commands are demodulated, decrypted, and provided to the MCU 107 over the communication links 109 via the UART enabled port. The MCU 107 converts the data into instructions and passes them on to the ZigBee® unit 310 via the bidirectional port 311 over the link 312. The ZigBee® unit 310 sends out commands to the ZigBee® technology enabled appliance connected to the Z-SW 300, based on received instructions, to execute operational commands of reading meters, changing temperature settings, etc. The response after the command has been executed is sent back to the built-in ZigBee® unit 310 by the ZigBee® technology enabled appliance, which then transfers it to information and passes it on to the MCU 107 via the bidirectional link 312 through the port 311. The MCU collects the information and forwards it with the address to be responded to by the broadband communication module 109 via communication links 108 connected to the UART enabled port on the communication module 109.

In the example of FIG. 3, the communication module 109 modulates the received information to a communication data stream for transmission over a broadband communication frequency band that is typically used for power line communication (PLC) over the AC power distribution lines within a local area network (LAN). The typical broadband used for PLC communication band in the 2 to 30 MHz range, providing up to a 200 Mbps data rate.

The communication module 109 sends out the modulated the data stream over the broadband connection 110 to a coupler filter 111 which is connected to the AC power distribution lines 101 by power line connections 112. The coupler filter acts as a bi-directional high pass filter to filter out power line frequency interference from the communication module. The broadband communication module 109 also demodulates the communication stream received over the AC power distribution lines 101 to provide the command and control instructions for power control and operational control to the MCU 107. The MCU 107 interprets any received command and control instructions to the power meter and instructs the power meter and relay module 104 for controlling the power flow to the power plug 103. The MCU 107 also interprets any operational command and instructions for the ZigBee® unit 310 and passes on these to the ZigBee® unit 310 to be directed to the ZigBee® technology enabled connected appliances.

### The Master Device (MST)

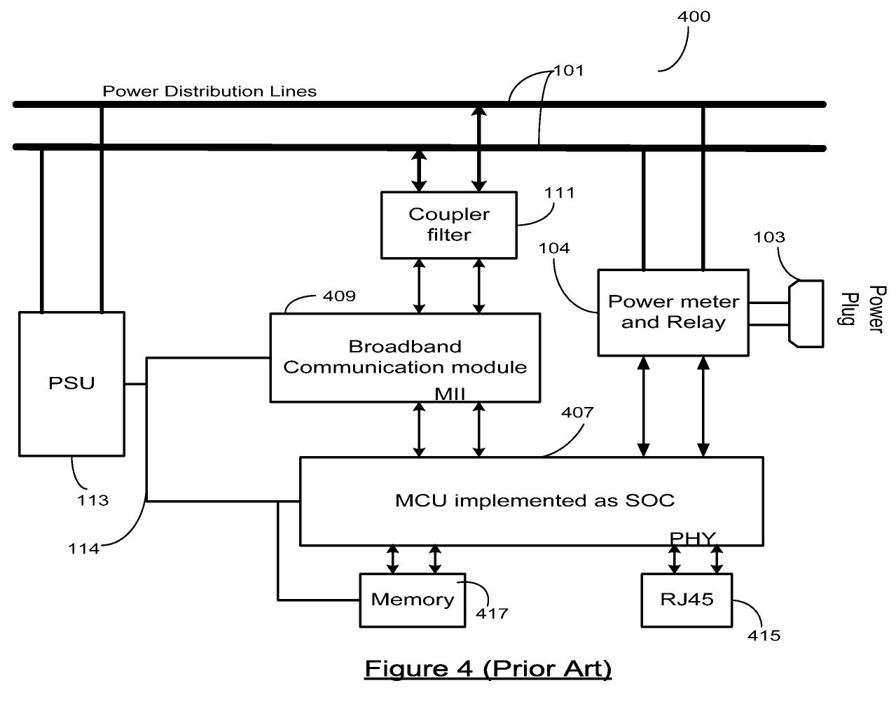

FIG. 4 is a block schematic diagram showing an MST 400. The MST 400 provides the computing power and storage capability necessary to collect and compile power consumption information provided to it. The MST enables the collected data to be transmitted to a wide area network for group compilation. The connected SW 100, ETH 200, and Z-SW 300 devices within the home or office monitor the power usage of devices and appliances connected to their respective power plugs. This information is sent over the local power distribution lines in the home or office to the MST 400 for compilation of data on usage. With the capability and computing power available and with appropriate software, the MST 400 can exert local and emergency control of the appliances connected to the SW 100, ETH 200, and Z-SW 300 devices. The MST 400 also acts as a gateway connecting to the broadband communication modem to enable a communication pathway to the internet cloud/wide area network (WAN) cloud.

In this implementation, a 32 bit MCU is provided as a system on chip (SOC) 407. The SOC 407 implementation provides for higher processing power and integration of modules with the MCU. The SOC 407 integrates a PHY into the MCU, allowing the RJ45 connector 415 to connect the customer's modem device directly to a port on the SOC 407. This connection is a 10/100 base TX, auto-negotiation Ethernet port and provides the gateway to the Internet through any connected modem for the PLC communication from all the connected ETH units within the PLC network. The typical communication module of the MST 400 uses, for example, any one chosen modulation scheme from the list of modulation protocols comprising OFDM, QAM1024/256/64/16, DQPSK, DBPSK, and ROBO, for sending and receiving communication data streams to the connected ETH units within the PLC network. The frequency band used for broadband PLC is 2 to 30 MHz, with a data transfer rate of up to 200 Mbps.

The gateway provided by the MST 400 is also used to send out the collected and processed information on the power usage and utility usage, as well as the status of the power monitoring and relay units within the PLC, for enabling control of the power plug 103. Any remote control commands are received from the Web via the gateway provided by the MST 400 for transfer to connected SW 100, ETH 200, and Z-SW 300 units for control of the power flow to connected appliances. In the MST 400, the modulation, frequency band, and data rates are the same as those used for the information and command transfer within the PLC network. The SOC 407 is enabled to enforce all communication related security protocols associated within the PLC network.

All data and power monitoring and control information is sent to the SOC 407 by the connected SW 100, Z-SW 300, and ETH 200 within the home or office via the power distribution lines 101 through the coupler filter module 111 and the communication module 409. The communication module 409 of the MST 400 is used to demodulate the incoming streams and decrypt them prior to transferring them to the MCU that forms part of the SOC 407. The SOC 407 receives the information and processes it, by compiling and consolidating it, for outward transmission to the Web.

The SOC 407 also has a memory 417 associated with it, typically connected to a memory port on the SOC 407. The memory 417 enables the SOC 407 to store the received power monitoring and control information prior to processing and compiling the information. The memory 417 is also used to store the compiled information to transmit it out through the gateway optimally when the bandwidth usage for data communication is low. The memory 417 also stores the transaction history with a timestamp for the data communication and power usage information transmitted out, and for incoming remote commands sent to the connected SW 100 and ETH 400 within the home or office. The memory 417 provides for tracking of performance and remote debugging capability with pinging and path tracking capability for the MST 400, as well as the connected SW 100 and ETH 200.

The MST 400 provides a power plug 103 of its own that is connected to the power distribution lines 101 through a power meter and relay 104 for connecting any needed appliance with the necessary power monitoring and control capability. This monitored information is sent to the MCU, which is implemented as an SOC 407, to be combined with the information received over the PLC LAN over the power distribution lines 101 through the coupler filter module 111 and the communication module 409. This collected information forms part of the power monitoring information input to the MST 400. The power monitoring information is stored in the memory and compiled and processed for transmission to the monitoring sources in the WAN through the modem connected to the SOC 407 port with the RJ45 connector 415. The transfer of the compiled information is typically done as in store and forward manner with storage in the memory 417 to enable best use of the available bandwidth of the gateway, as discussed earlier.

Remote control commands received via the gateway are received through duplex port with the RJ45 connector 415 from the connected modem. These control commands are interpreted by the SOC 407 of the MST 400 and sent to the respective SW 100, ETH 200, or Z-SW 300 to which it is addressed over the broadband PLC network through communication module 409 and coupler filter module 111 for necessary action at the addressed receiving units.

Typical Connection for the Devices within the Home or Office to Enable Collection and Compilation of Power and Utility Data

FIG. 5 (also discussed above) is a block schematic diagram of a PLC network 500 that provides power monitoring and management, utility monitoring, and that also provides communication connectivity, using the four devices described above, namely one MST, and one or more of the SW, ETH, and Z-SW. In FIG. 5, the PLC network includes a few of the possible connected items found in a home as an example and is not a comprehensive list of connected items.

The SW unit 541 shown as part of the PLC network 500 is used where the requirement is for power connection capability with monitoring and control, but without the need to connect a communication device into the PLC network. In the PLC network 500, the SW 541 is used to connect an oven 523 to the power line with power monitoring capability.

The ETH devices 551 to 554 allow communication devices to be connected to the PLC LAN, while providing a power plug or power source which can be monitored and controlled where needed. In the PLC network 500, the ETH 551 is connected to a telephone system 520, the ETH 552 is connected to the computer 522, the ETH 553 is connected to an IP-TV 524, and the ETH 554 connected to the home security system 525.

With regard to the Z-SW devices in the PLC network 500, some of these devices are used to provide power to connected appliances and to control the operation of the appliance, as in the Z-SW 561 which is connected to the ZigBee® enabled refrigerator 526, and the Z-SW 562 which is connected to the home climate control unit 527, and other devices are used to collect usage information of a utility for billing and monitoring, as in the case of the Z-SW 563 which is connected to the ZigBee® enabled water meter and the Z-SW 564 which is connected to the ZigBee® enabled gas meter.

There is a single MST for each in-home or office PLC network. In the PLC network 500, the MST 531 is connected to a router 521 that is connected to the xDSL or other broad band access gateway 510 to the Internet/WAN 505. This establishes a connection to the WAN 505, enabling the PLC network 500 to communicate with the outside world in accordance with security and connection rules. The power plug of the MST is used provide power supply with power monitoring and control capability to the router 521.

Multiple SW, Z-SW, and ETH devices with a single MST device can be used to establish the power and utility monitoring and control for the home and provide connectivity for data communication using the PLC network.

Because communication connections to the WAN 505 and within the PLC network 500 are all broadband enabled, the system is able to provide steaming media capability within the PLC network 500 using the ETH 552 connected to computer 522 and the ETH 553 connected to the IP-TV 524. The PLC network 500 can access and enable streaming media delivery to the ETH 552 and ETH 553 connected display devices, through the MST 531 via the router 521 connected to the WAN 505.

The MST 531 is also used as a collection and compilation point for the power and utility usage. Information concerning power usage and other utility usage within the home over pre-specified periods of time that is received from the connected SW 541, Z-SW 561 to 564, ETH 551 to 554, and MST 531 is consolidated and compiled using the capability in the MCU 407 of the MST 531, and stored in the memory module 417 of the MST 531. Each of the connected devices SW 541, ETH 551 to 554, and Z-SW 561 to 564 is provided with a unique identity number to enable traceability of the monitoring and control of the collected monitoring and control functions.

Because there is connectivity with control capability on each of the SW 541, Z-SW 561 to 564, ETH 551 to 554, and MST 531 devices, the power delivery through each of these SW and ETH units can be monitored and controlled from any of the communication devices connected to the PLC network. The collected information is compiled and stored in a traceable format in the memory 417 of the MST 531 using the identity number for traceability.

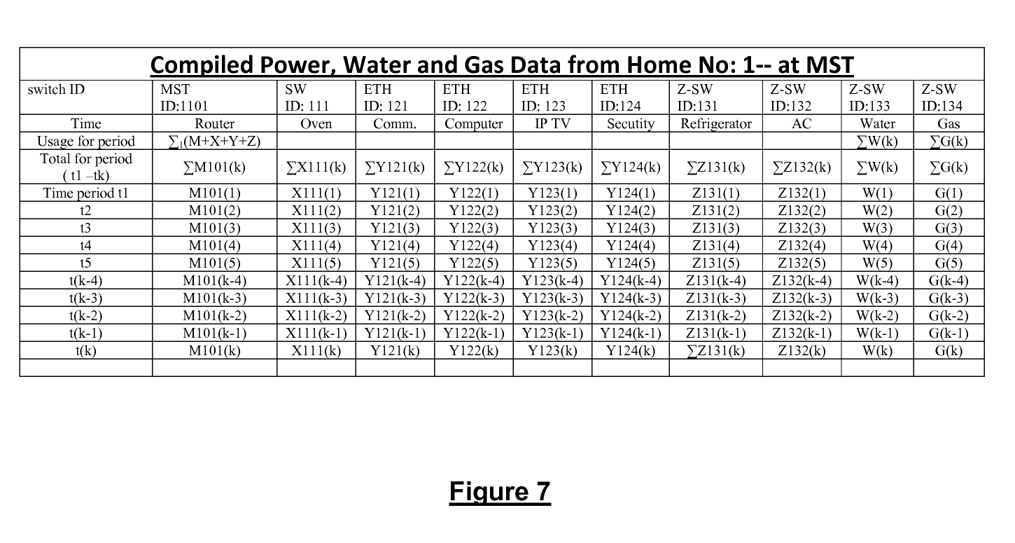

A compilation of the power and utility information 700 collected from a home over the PLC network 500 from the connected appliances is shown in FIG. 7. As shown in the compilation of the power and utility information 700, each collection device has a unique n digit ID number (three in this exemplary case) of which the first is used to identify the home number, the second the type of collection device (MST, SW, ETH, or Z-SW), and the third the serial number of the collection device within a PLC network Further, this collected information in the compiled form or information on instantaneous usage, with respect to any of the appliances connected to SW 541, ETH 551 to 554, Z-SW 561 to 564, or MST 531, can be accessed from the WAN 505 using connected communication devices to monitor the status and to provide remote control commands through the gateway established via xDSL 510 using the router connection 521. This capability is controlled by the permissions, authorizations, and security rules established for connection into the PLC network 500 through the MST 531.

### Green Energy, Smart Grid Residential System

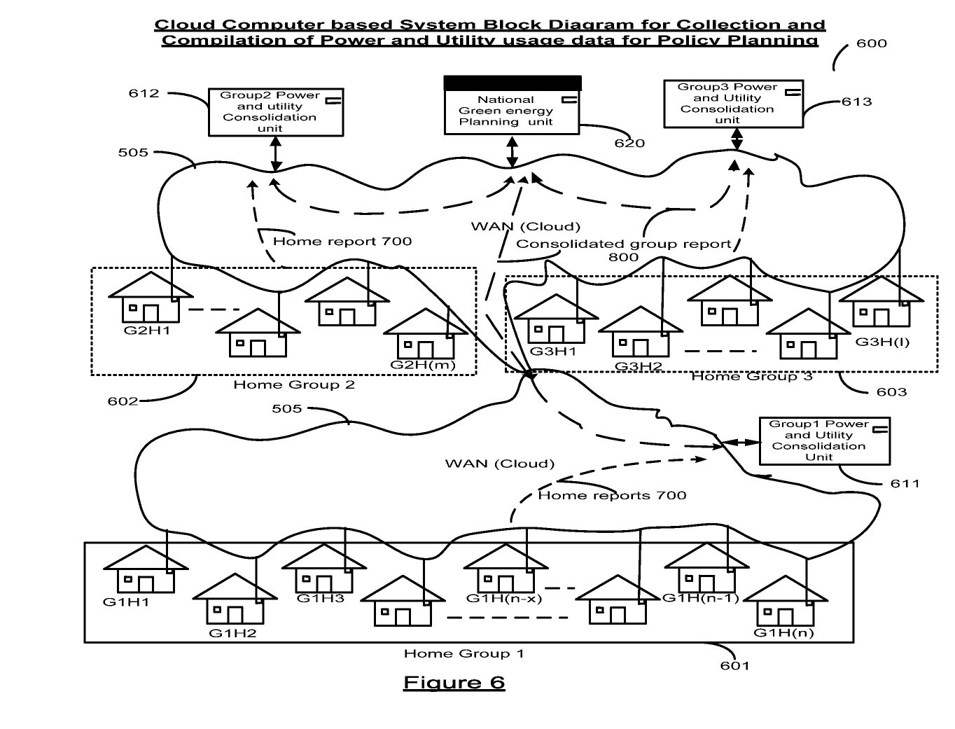

FIG. 6 is a block schematic diagram showing a green energy smart-grid residential system 600 for data collection from homes. The data on power usage and utility usage that is collected and compiled by the MST 531 from each home in a home group, such as Home Group 1 601, is sent over the Internet to a local power and utility consolidation and computing system, such as the Group1 power and utility consolidation unit 611. The local power and utility consolidation and computing system may be a dedicated computer system or, more typically, a computing capability in a WAN 505.

Similar to Home Group 1, the collected and compiled data from each home in Home Group 2 602 is sent to the Group2 power and utility consolidation unit 612, and the information from Home Group 3 603 is sent to the Group3 power and utility consolidation unit 613. Each home in a home group provides to the group power and utility consolidation system associated with it the details of the connected power and utility usage, typically in the format of compilation of power and utility information 700, as shown in FIG. 7, with all the connected appliances in the home.

Using WAN based computing capability in the local area reduces compilation costs associated with large capacity dedicated systems that are needed to do the collection, storage, tracking, and compilation of data received from homes in a home group. This data received from all the homes in the Home Group 1 601, for example, is then stored, compiled, and consolidated by the Group1 power and utility consolidation unit 611.

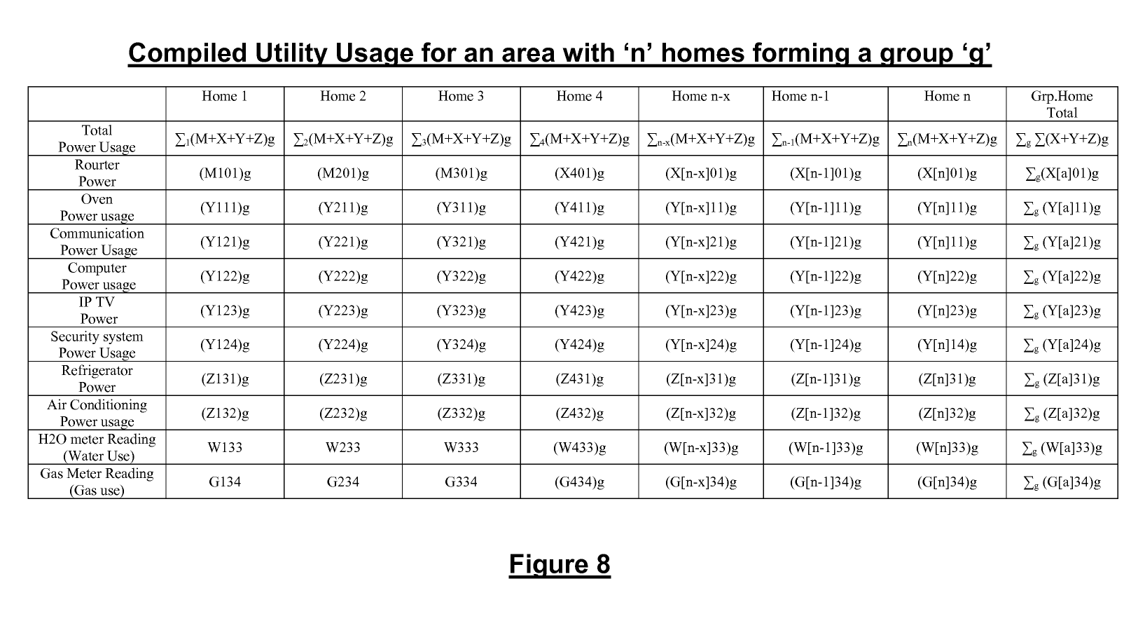

A typical output format for the consolidated information, shown in FIG. 8, provides the compiled utility usage for an area of ‘n’ homes forming a group ‘g’ 800. This format at group level provides traceability for data from each home and each connected appliance in the home in the consolidated statement. Such traceability is essential to compare the effectiveness of any incentive plans when they are being tested for implementation, as discussed later.

The local collected and compiled data from the various group (1, 2, 3) power and utility consolidation units, such as 611, 612, and 633 is then sent to the next level, which may be the state or national level, for consolidation. The ultimate aim of such a hierarchical system is to provide traceable power and utility usage information to state and national level policy makers. In FIG. 6, for example, a national green energy planning unit 620, which is a final consolidation and computing unit, receives the locally consolidated information from the WAN from each group (1, 2, and 3) power and utility consolidation units 611, 612, and 613, indicating the compiled utility usage for an area of ‘n’ homes forming a group ‘g’ 800 with full traceability. This information is compiled by the national green energy planning system into a national green energy data base for use in developing national policy on green energy. Using the computing capability available in the national green energy planning unit 620 the received information is compiled to a national format and stored. The national green energy planning system, using its computing power, generates reports based on the green energy data base to provide to the policy makers the necessary information to assimilate the usage patterns. The policy makers can then, based on valid verifiable information, put forward policy and incentive plans to reduce the usage of power and other utilities to control the growth of the carbon foot print of each home and, hence, the nation.

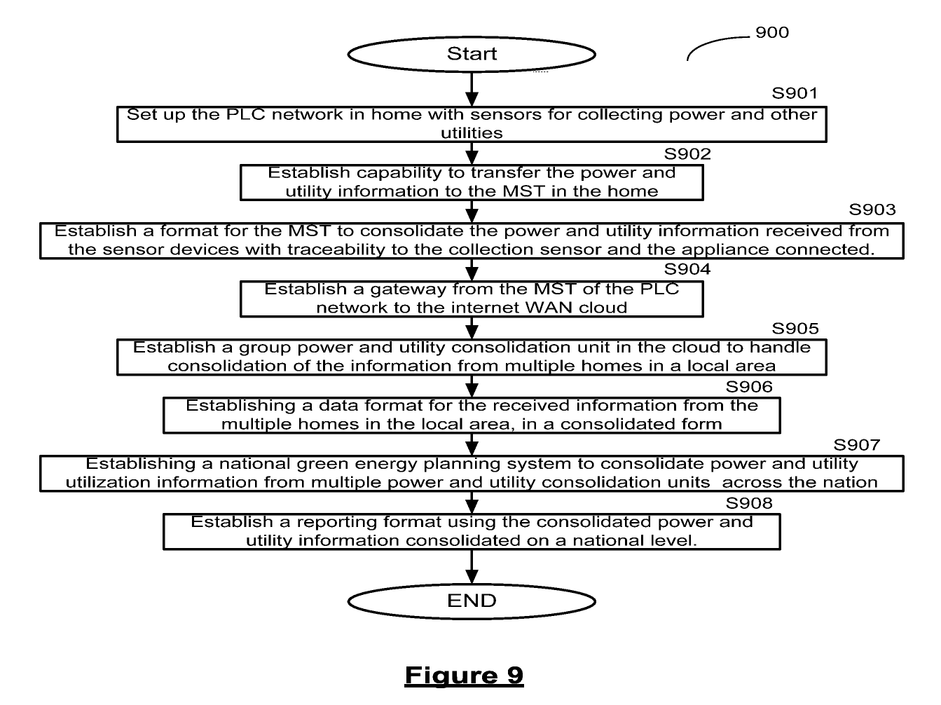

FIG. 9 is a flow chart 900 showing an implementation for the establishment of the power and utility consolidation capability enabled for the creation of a national green energy data base.

The in-home PLC network is set up with the necessary sensors to enable collection of power usage information using the power plugs enabled for monitoring and utility usage measurement through the ZigBee® technology using ZigBee® enabled meters connecting to the sensors (S901).

The sensors deliver the collected power and utility usage information to the in-home MST device over the PLC network for storage and compilation (S902).

A format is established for the MST to generate a consolidated compilation of the received power and utility usage information which retains the capability for information traceability to the collecting sensors (S903).

An Internet gateway is set up and established from the in-home MST to the WAN for information transfer to and from the WAN based units (S904).

A group power and utility consolidation unit is set up and configured, typically in the WAN, to receive power and utility usage information from multiple local homes, thus forming a home group having sufficient CPU computational power and storage capability to provide for consolidation and storage of the received power and utility usage information (S905).

Establish a data format on the group power and utility unit for the compiled power and utility usage information received from the individual MSTs of the home group. The data format being capable of providing traceability and authentication of the original collected data by enabling identification of the home and the sensor within the home used to collect the power or utility usage data. S906.

A national green energy planning system is established, having enough computing power to collect and consolidate the power and utility information received from the multiple local area group power and utility consolidation units across the nation to create a green energy data base, while keeping the traceability of the information collected (S907).

The national green energy planning system is further enabled to generate reports for the policy makers to assimilate and define effective policy to achieve reduction of greenhouse gases at the home and at national level (S908).

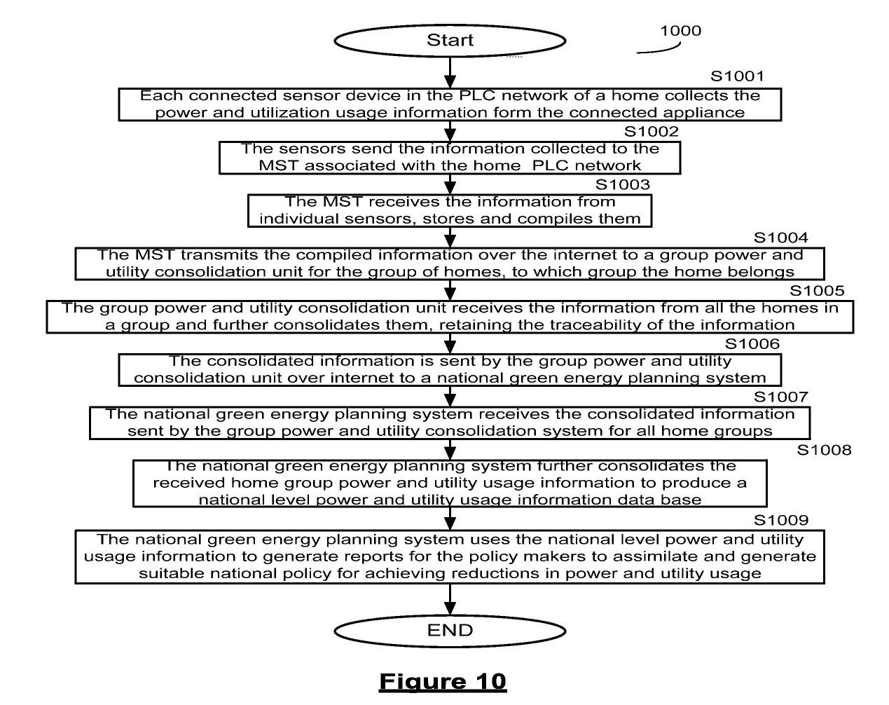

FIG. 10 is a flowchart 1000 showing the operation of the green energy smart-grid residential system that generated a national green energy database and that provides reports to the national policy makers regarding the power and other utilities, such as water and gas usage.

The power usage within a home is collected by the connected sensor devices that include SW, Z-SW, ETH, and MST devices having power plugs and the other utility usage, as collected by the Z-SW using the ZigBee® technology from ZigBee® enabled meters (S1001).

The information is sent by the collecting sensors in the home over the PLC network of the home to the MST device of the home for collection and compilation and storage (S1002).

The MST of the home receives the information sent over the PLC network of the home. This information is accepted, stored, compiled, and stored again in a deliverable format, keeping the traceability of the information to individual appliance or meters in the home (S1003).

The MST transmits the compiled information through the connected Internet gateway and the WAN to a local group power and utility consolidation unit. Such a group power and utility consolidation unit, having sufficient computing power, is established typically in the WAN for each of such local group of homes to which a set of local homes belongs (S1004).

The group power and utility consolidation unit receives the information on power usage from the MST devices of each of the homes in the home group and consolidates the information received. The consolidated power and utility information in the consolidated form is designed to maintain the traceability to the original collection point for authentication (S1005).

The group level consolidated information is sent over the Internet to a national green energy planning system established, with sufficient computing and memory capability, to collect and compile the national level power and utility usage information (S1006).

The national green energy planning system receives the power and utility information sent by the group power and utility consolidation units covering all different local areas in the nation (S1007).

The national green energy planning system combines the inputs from various home groups, stores them, and consolidates the power and utility usage information to develop a national power and utility usage data base with full traceability of information to the collection points for verification of data (S1008).

The national power and utility usage information database is used to generate reports for assimilation by the policy makers, who can then define an effective national policy on green energy to reduce the power and utility usage. This may include changing the cost structure for the consumer, providing incentives for converting to more efficient appliances, and implementing incentive schemes for reduced utility usage. Such policies can be oriented at reducing the overall power and utility usage of homes and hence reduce the carbon footprint of the homes and the nation (S1009).

The green energy smart-grid residential system is also capable of doing comparative studies and providing sampling results of possible policy changes and incentive plans proposed for improving the impact policy being proposed.

Typically, before any new incentive plans are introduced to induce the consumer to change his behavioral pattern of power and utility usage, the plan must be tested out for effectiveness on a sample population. For example, providing an incentive to the consumer to change from using incandescent bulbs to low energy fluorescent bulbs, or providing an incentive to change from high water flow flush to a low water flow flush, etc. It is very important to test this traceability. One home group, e.g. Home Group 1 601, may be used as a test subject while Home Group 2 602 and Home Group 3 603 are used as standards. When a monetary incentive or other type of incentive scheme is provided to the Home Group 1 601 to change from high water flow flush to a low water flow power flush, the data collected from the water meter over a period of time shows the effectiveness of the incentive to push the customer to change his flush to a low water flow flush. It also shows the impact the incentive has in reducing the overall water usage within the selected group. If these results show that the incentive scheme is cost effective, then it can be considered for implementation on a national level as part of national policy on water conservation policy. Such checks can also be used to decide the most effective policies from a number of available policy alternatives. The capability to trace the usage of power and other utility within a home, and to identify homes which implement specific upgrades and trace its impact, becomes critical in these studies. Such a capability is provided by the disclosed invention.

A person skilled-in-the-art would readily appreciate that the invention disclosed herein is described with respect to specific exemplary embodiments of the devices and systems currently used. It is also possible to provide other formats for presentation of the collected data and information, which may be more in line with the policy maker's needs. However, these described embodiments should not be considered limitations on the scope of the invention. Specifically, other implementations of the disclosed invention are envisioned and hence the invention should not be considered to be limited, to the specific embodiments discussed herein above. The system may be implemented with processing in dedicated central computing facility, in distributed computing facility in the WAN, or a combination of the two. The units, devices, and systems may be implemented as hardware and/or software implemented and running over hardware such as computers, distributed or otherwise, as assembly of individual components, as a combination of components and integrated circuits, or SOCs. The invention should not be considered as being limited in scope based on specific block level details, but should be considered on the basis of current and future envisioned functionality.

Although the invention is described herein with reference to the preferred embodiment, one skilled in the art will readily appreciate that other applications may be substituted for those set forth herein without departing from the spirit and scope of the present invention. Accordingly, the invention should only be limited by the Claims included below.

1. An apparatus for monitoring power usage by one or more appliances at each individual location within a group of locations, comprising:
a master unit (MST) connected to a power distribution line, said MST in communication with a power switch unit (SW) and/or a communication enabled power switch unit (ETH) via said power distribution line and configured for collection and compilation of power usage information from said SW and/or said ETH; and
said MST configured as a communication gateway to a wide area network (WAN) for a local area network (LAN);
wherein said collected and compiled power usage information is formatted for transmission over said WAN to at least one group power and utility consolidation unit for group level data and information compilation; and
further comprising at least one of:
a power switch unit (SW) connected to said power distribution line for monitoring and controlling power usage of at least one appliance connected to said SW; and
a communication enabled power switch unit (ETH) connected to said power distribution line, said ETH configured to provide power line communication (PLC) and thereby from said (LAN) over said power distribution line;
wherein said ETH is configured for monitoring and control of power usage by appliances connected between said ETH and said power distribution line.

2. The apparatus of claim 1, further comprising:
at least one SW configured for monitoring and controlling power usage and at least one ETH configured for establishing LAN, for monitoring and controlling power usage of said at least one appliance, and for transferring said collected and compiled power usage information over said power distribution line.

3. The apparatus of claim 1, wherein said MST is configured for either of narrowband and broadband transfer of collected power usage and control information over said power distribution line.

4. The apparatus of claim 1, wherein said collected and compiled power usage information formatted for transmission over said WAN to said at least one group power and utility consolidation unit for group level data and information compilation by a national green energy planning system for national level use.

5. The apparatus of claim 1, wherein said collected and compiled power usage information formatted into a traceable form for transmission over said WAN to said at least one group power and utility consolidation unit, said at least one group power and utility consolidation unit comprising a national green energy planning system configured for collecting said power usage information and for reporting said collected power usage information to policy makers.

6. An apparatus for monitoring of power usage by one or more appliances at each individual location within a group of locations, comprising:
at least one group power and utility consolidation unit for group level data and information compilation of collected and compiled power usage information received over a wide area network (WAN) from each individual location within said group of locations, said collected and compiled power usage information received from each said location as collected over a local area network (LAN) from a master unit (MST) at each said location that is connected to a power distribution line.

7. The apparatus of claim 6, further comprising:
a facility configured for receiving group level data and information from each said group power and utility consolidation unit; and configured for effecting one or more comparative studies and for providing sampling results in connection with proposed policy changes and/or incentive plans by testing said policy changes and/or incentive plans for effectiveness on a sample population.

8. The apparatus of claim 6, wherein said MST is configured as a communication gateway to said WAN for said LAN, said MST in communication with a power switch unit (SW) and/or a communication enabled power switch unit (ETH) via said power distribution line and configured for collection and compilation of said power usage information from said SW and/or said ETH.

9. A system, comprising:
a plurality of group power and utility consolidation units that are linked via a wide area network (WAN) to provide a green energy smart-grid, wherein:
each said group power and utility consolidation unit is linked via said WAN with a national green energy planning unit; and
each said group power and utility consolidation unit is linked via said WAN with an Internet gateway at each of a plurality of locations in a local area, said plurality of locations defining a home group, wherein:
each said Internet gateway is connected to a master device via a power line communication (PLC) network at a corresponding one of said plurality of locations, the PLC network at each said location comprising one or more sensor devices that are configured for collecting, compiling, and storing power and utility usage information for said location.

10. The system of claim 9, wherein each Internet gateway is configured to transfer said collected and compiled power and utility information via the Internet from each said location to a corresponding group power and utility consolidation unit that is linked to said plurality of locations within said home group.

11. The system of claim 10, wherein each said group power and utility consolidation unit is configured to receive said compiled power and utility usage information from each said corresponding location within said home group, and is configured to consolidate, compile, and store said information for said corresponding home group.

12. The system of claim 11, wherein each said group power and utility consolidation unit is configured to send out consolidated power and utility usage information over the Internet to said national green energy planning system for each corresponding home group.

13. The system of claim 12, wherein said national green energy planning unit is configured to receive said consolidated power and utility information from each said home group and compile and consolidate said power and utility information to populate a consolidated power and utility information database, wherein said database stores said information with full traceability; and
wherein said national green energy planning unit configured to access said database to generate one or more reports for use by policy makers to enable creation of a national policy for reduction of green-house gasses.

14. The system of claim 9, said green energy planning unit configured for receiving group level data and information from each said group power and utility consolidation unit; and configured for effecting one or more comparative studies and for providing sampling results in connection with proposed policy changes and/or incentive plans by testing said policy changes and/or incentive plans for effectiveness on a sample population.

15. A method for monitoring power usage by one or more appliances at each individual location within a group of locations, comprising:
providing a master unit (MST) connected to a power distribution line, said MST in communication with a power switch unit (SW) and/or a communication enabled power switch unit (ETH) via said power distribution line and configured for collection and compilation of power usage information from said SW and/or said ETH; and
said MST configured as a communication gateway to a wide area network (WAN) for a local area network (LAN);
wherein said collected and compiled power usage information is formatted for transmission over said WAN to at least one group power and utility consolidation unit for group level data and information compilation; and
further comprising providing at least one of:
a power switch unit (SW) connected to said power distribution line for monitoring and controlling power usage of at least one appliance connected to said SW; and
a communication enabled power switch unit (ETH) connected to said power distribution line, said ETH configured to provide power line communication (PLC) and thereby from said (LAN) over said power distribution line;
wherein said ETH is configured for monitoring and control of power usage by appliances connected between said ETH and said power distribution line.

16. A method for monitoring of power usage by one or more appliances at each individual location within a group of locations, comprising:
effecting group level data and information compilation of collected and compiled power usage information received over a wide area network (WAN) from each individual location within a group of locations, said collected and compiled power usage information received from each said location as collected over a local area network (LAN) from a master unit (MST) at each said location that is connected to a power distribution line.

17. The method of claim 16, further comprising:
providing a facility configured for receiving group level data and information from each said group power and utility consolidation unit; and configured for effecting one or more comparative studies and for providing sampling results in connection with proposed policy changes and/or incentive plans by testing said policy changes and/or incentive plans for effectiveness on a sample population.

18. A method, comprising:
linking a plurality of group power and utility consolidation units via a wide area network (WAN) to provide a green energy smart-grid, wherein:
each said group power and utility consolidation unit is linked via said WAN with a national green energy planning unit; and
each said group power and utility consolidation unit is linked via said WAN with an Internet gateway at each of a plurality of locations in a local area, said plurality of locations defining a home group, wherein:
each said Internet gateway is connected to a master device via a power line communication (PLC) network at a corresponding one of said plurality of locations, the PLC network at each said location comprising one or more sensor devices that are configured for collecting, compiling, and storing power and utility usage information for said location.

19. The method of claim 18, further comprising:
configuring said green energy planning unit for receiving group level data and information from each said group power and utility consolidation unit; and configured for effecting one or more comparative studies and for providing sampling results in connection with proposed policy changes and/or incentive plans by testing said policy changes and/or incentive plans for effectiveness on a sample population.

20. An electronic storage medium having stored therein program instructions which, when executed by a processor, execute the method of any of claim 15.
